(19) United States
(12) Patent Application Publication
(10) Pub. No.: US 2018/0342473 A1
(43) Pub. Date: Nov. 29, 2018

(54) VIA STRUCTURE, SUBSTRATE STRUCTURE INCLUDING THE SAME, AND METHOD FOR MANUFACTURING THE SAME

(71) Applicant: Advanced Semiconductor Engineering, Inc., Kaohsiung (TW)

(72) Inventors: Wen-Long LU, Kaohsiung (TW); Yuan-Feng CHIANG, Kaohsiung (TW); Tsung-Tang TSAI, Kaohsiung (TW)

(73) Assignee: Advanced Semiconductor Engineering, Inc., Kaohsiung (TW)

(21) Appl. No.: 15/605,897

(22) Filed: May 25, 2017

(51) Int. Cl. H01L 23/00

(52) U.S. Cl. CPC H01L 24/05; H01L 24/13; H01L 24/03; H01L 2224/13025; H01L 2224/0401; H01L 2224/04105; H01L 2224/03015; H01L 2224/05018; H01L 2224/05027; H01L 2224/0311; H01L 2224/0312; H01L 2224/0391; H01L 2224/05009

(57) ABSTRACT

A via structure includes a base material, a first dielectric layer and a second dielectric layer. The base material includes a first surface and a second surface opposite to the first surface, and defines at least one through hole. The first dielectric layer is disposed on the first surface of the base material and includes a gradient surface exposed in the through hole of the base material. The second dielectric layer is disposed on the gradient surface of first dielectric layer.

### BACKGROUND

### 1. Field of the Disclosure

The present disclosure relates to a via structure, a substrate structure and a manufacturing method, and more particularly to a via structure including a dielectric layer having a gradient surface in a through hole, a substrate structure including the via structure, and a method for manufacturing the via structure.

### 2. Description of the Related Art

In a semiconductor package, a conductive via is included for electrical connection between different layers of the semiconductor package. The formation of the conductive via may include forming a hole on a substrate, and then forming a dielectric layer covering a surface of the substrate and a sidewall of the substrate defining the hole. The dielectric layer is generally formed by curing a photoimageable material, such as a polymer. However, a nodule (e.g., a protrusion of the dielectric layer) may be formed adjacent to two ends of the sidewall of the hole, which may result in defect of the conductive via.

### SUMMARY

In some embodiments, according to an aspect, a through via structure includes a base material, a first dielectric layer and a second dielectric layer. The base material includes a first surface and a second surface opposite to the first surface, and defines at least one through hole. The first dielectric layer is disposed on the first surface of the base material and includes a gradient surface exposed in the through hole of the base material. The second dielectric layer is disposed on the gradient surface of first dielectric layer.

In some embodiments, according to another aspect, a substrate structure includes a base material and a first dielectric layer. The base material includes a first surface and a second surface opposite to the first surface, and defines least one through hole. The first dielectric layer is disposed on the first surface of the base material and includes a gradient surface exposed in the through hole.

In some embodiments, according to another aspect, a method for manufacturing a via structure includes: (a) forming a first dielectric layer on a base material of a substrate; (b) forming at least one through hole extending through the base material to expose the first dielectric layer in the through hole; (c) forming a second dielectric layer on a sidewall of the through hole of the base material, wherein a first portion of the first dielectric layer is exposed in the through hole and uncovered by the second dielectric layer; and (d) removing the first portion of the first dielectric layer.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a package structure including a via structure according to some embodiments of the present disclosure.

FIG. 2 illustrates an enlarged view of the area A in FIG. 1.

FIG. 2A illustrates a cross-sectional view of a portion of a package structure including a via structure according to some embodiments of the present disclosure.

FIG. 3 illustrates an example of a via structure according to some embodiments of the present disclosure.

FIG. 4 illustrates an example of a via structure according to some embodiments of the present disclosure.

FIG. 5 illustrates an example of a via structure according to some embodiments of the present disclosure.

FIG. 6 illustrates a stacked structure including a plurality of substrate structures according to some embodiments of the present disclosure.

FIG. 7 illustrates one or more stages of an example of a method for manufacturing a via structure according to some embodiments of the present disclosure.

FIG. 8 illustrates one or more stages of an example of a method for manufacturing a via structure according to some embodiments of the present disclosure.

FIG. 9 illustrates one or more stages of an example of a method for manufacturing a via structure according to some embodiments of the present disclosure.

FIG. 10 illustrates one or more stages of an example of a method for manufacturing a via structure according to some embodiments of the present disclosure.

FIG. 11 illustrates one or more stages of an example of a method for manufacturing a via structure according to some embodiments of the present disclosure.

FIG. 12 illustrates one or more stages of an example of a method for manufacturing a via structure according to some embodiments of the present disclosure.

FIG. 13 illustrates one or more stages of an example of a method for manufacturing a via structure according to some embodiments of the present disclosure.

FIG. 14 illustrates one or more stages of an example of a method for manufacturing a via structure according to some embodiments of the present disclosure.

FIG. 15 illustrates one or more stages of an example of a method for manufacturing a via structure according to some embodiments of the present disclosure.

FIG. 16 illustrates one or more stages of an example of a method for manufacturing a via structure according to some embodiments of the present disclosure.

FIG. 17 illustrates one or more stages of an example of a method for manufacturing a via structure according to some embodiments of the present disclosure.

FIG. 18 illustrates one or more stages of an example of a method for manufacturing a via structure according to some embodiments of the present disclosure.

FIG. 19 illustrates one or more stages of an example of a method for manufacturing a via structure according to some embodiments of the present disclosure.

FIG. 20 illustrates one or more stages of an example of a method for manufacturing a via structure according to some embodiments of the present disclosure.

FIG. 21 illustrates one or more stages of an example of a method for manufacturing a via structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

At least some embodiments of the present disclosure disclose an via structure which includes a dielectric layer having a gradient surface in a through hole of the via structure. At least some embodiments of the present disclosure further disclose a substrate structure including the via structure, and techniques for manufacturing the via structure.

According to some embodiments, a method for manufacturing a via structure may include the following steps. Firstly, a substrate is provided. The substrate includes a base material, a first dielectric layer disposed on the base material, and a first conductive layer disposed on the first dielectric layer. Then, a through hole is formed by etching a portion of the base material and etching a portion of the first dielectric layer. The through hole extends through the base material and the first dielectric layer, such that a portion of the first conductive layer is uncovered by the first dielectric layer and is exposed in the through hole. Then, a “negative” acting photoimageable material is formed on the base material and fills the through hole. For the “negative” acting photoimageable material, a portion of the material uncovered by a mask is to be cured by a radiation (rendered insoluble to a developer); while another portion of the material covered by the mask is to remain uncured (soluble to the developer) and then to form a dielectric layer.

A mask is disposed above the through hole, and the photoimageable material is exposed to a radiation source. A portion of the photoimageable material, which is uncovered by the mask, is thus cured. After radiation, the other portion of the photoimageable material, which is covered by the mask and thus not cured, is dissolved in a developer, thus forming a second dielectric layer on the base material. The second dielectric layer extends into the through hole to cover a sidewall of the through hole and a part of the portion of the first conductive layer exposed in the through hole. Then, a second conductive layer is formed on the base material and extends into the through hole to physically contact the first conductive layer.

Since the photoimageable material is “negative” acting, light beams reflected by the base material and the first conductive layer may result in undesired nodules. For example, the etching process for completely removing the portion of the first dielectric layer exposed in the through hole may adversely cause a large-scale chamfer portion formed on an edge of the base material adjacent to the through hole. A portion of light beams may be reflected by the chamfer portion and thus cures the photoimageable material around the corner, resulting in a nodule of the second dielectric layer adjacent to an upper end of the through hole. On the other hand, since the first conductive layer is exposed in the through hole, another portion of light beams may be reflected by the first conductive layer and thus cures the photoimageable material near the sidewall of the through hole, resulting in a nodule at a lower end of the through hole. Due to the existence of the nodules, the second conductive layer may not be sufficiently formed inside the through hole to physically contact the first conductive layer, thus causing failure of the via structure. In some embodiments, the smaller the diameter of the through hole, the more noticeable is the effect of the nodule.

At least some embodiments of the present disclosure address at least the above concerns and disclose a via structure and a substrate structure including the same, and techniques for manufacturing the via structure. In one or more embodiments of the present disclosure, the nodules of the dielectric layer can be sufficiently avoided, which improves the yield rate of the via structure.

FIG. 1 illustrates an example of a substrate structure 1 according to some embodiments of the present disclosure. The substrate structure 1 includes a base material 3, a first dielectric layer 4, a second dielectric layer 5, a first conductive layer 6 and a second conductive layer 7, an active layer 11, a passivation layer 12, a plurality of solder balls 14 and a plurality of under bump metallization (UBM) layers 13.

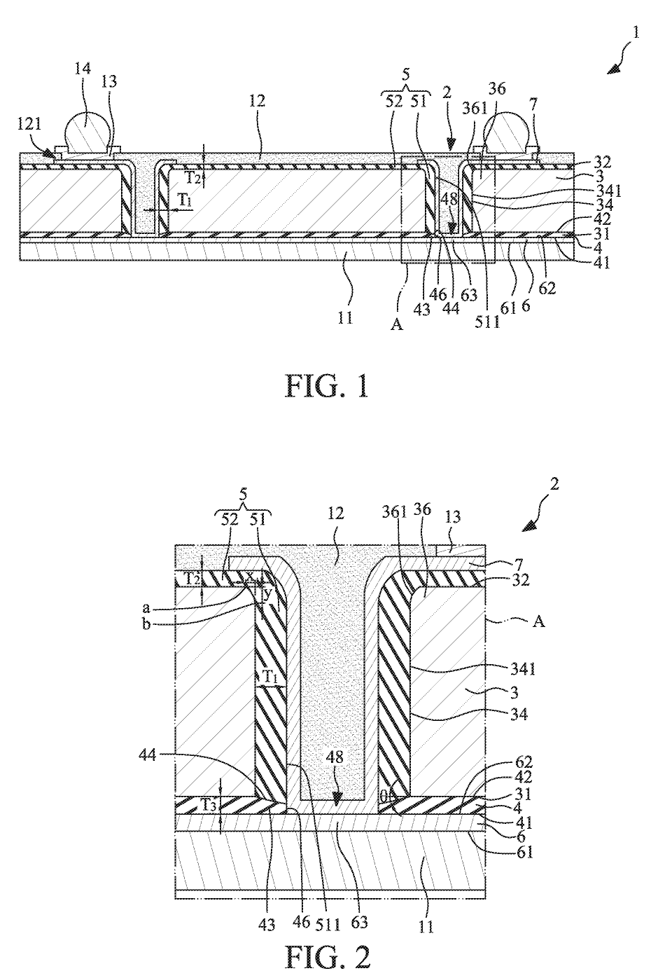

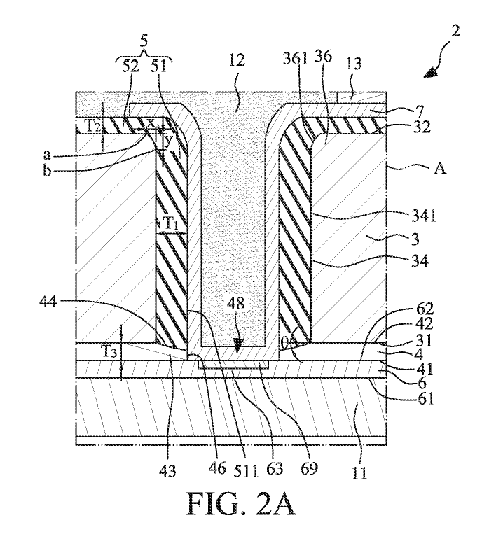

FIG. 2 is an enlarged view of the area A of FIG. 1, which illustrates a via structure 2 according to some embodiments of the present disclosure. The via structure 2 includes a portion of the base material 3, a portion of the first dielectric layer 4, a portion of the second dielectric layer 5, a portion of the first conductive layer 6 and a portion of the second conductive layer 7.

The base material 3 includes a first surface 31 and a second surface 32 opposite to the first surface 31, and defines a through hole 34 extending through the base material 3. The material of the base material 3 may include, for example, a semiconductor material (e.g., silicon), glass, ceramic, organic material, metal (e.g. Cu, Ni, Ag/Sn, and Pd), or a combination of two or more thereof. The base material 3 further includes a chamfer portion 36 at an edge adjacent to an upper portion of the through hole 34. In one embodiment, the chamfer portion 36 may be a round corner. For example, the through hole 34 has a sidewall 341, and the chamfer portion 36 is connected between the second surface 32 of the base material 3 and the sidewall 341 of the through hole 34. A surface 361 of the chamfer portion 36 intersects with the second surface 32 of the base material 3 at a point “a”, and intersects with the sidewall 341 of the through hole 34 at a point “b.” A distance “x” between the point “a” and the sidewall 341 of the through hole 34 is measured along the second surface 32 of the base material 3. In some embodiments, the distance “x” may be, e.g., from about 0.01 micrometer (μm) to about 10 μm, from about 0.01 μm to about 5 μm, from about 0.01 μm to about 2.25 μm, from about 0.01 pm to about 1 μm, or from about 0.01 μm to about 0.5 μm. In one embodiment, for example, 0.01 μm≤x≤2.25 μm. A distance “y” between the point “b” and the second surface 32 of the base material 3 is measured along the sidewall 341 of the through hole 34. In one embodiment, the distance “y” may be greater than the distance “x.” Alternatively, the distance “y” may be substantially equal to the distance “x.”

The first dielectric layer 4 is disposed on the first surface 31 of the base material 3. The material of the first dielectric layer 4 may include, for example, oxides, nitrides, or a combination of two or more thereof. The first dielectric layer 4 includes a first surface 41 and a second surface 42 opposite to the first surface 41. The second surface 42 of the first dielectric layer 4 faces and is disposed on the first surface 31 of the base material 3. The first dielectric layer 4 includes an intermediate portion 43 extending into the through hole 34 of the base material 3. The intermediate portion 43 includes a gradient surface (or slant or sloped surface) 44 and an inner surface 46. The gradient surface 44 connects the second surface 42 and is exposed in the through hole 34 of the base material 3. The inner surface 46 extends between the gradient surface 44 and the first surface 41. The gradient surface 44 extends from the sidewall 341 of the through hole 34 downward toward a center (e.g. a central axis) of the through hole 34. For example, the first dielectric layer 4 has a thickness T₃ decreasing from the sidewall 341 of the through hole 34 toward the center of the through hole 34, thus forming the intermediate portion 43 and the gradient surface 44. An angle “θ” formed between the second surface 42 and the gradient surface 44 of the first dielectric layer 4 may be in a range, e.g., from about 0.01 degree to about 30 degrees, from about 0.05 degrees to about 15 degrees, from about 0.05 degree to about 15 degrees, or from about 0.1 degree to about 4 degrees. The inner surface 46 of the intermediate portion 43 of the first dielectric layer 4 defines an opening 48 within the through hole 34 of the base material 3.

The second dielectric layer 5 is disposed on the gradient surface 44 of the first dielectric layer 4. The second dielectric layer 5 may include, or be formed from, a cured photoimageable dielectric (PID) material or a cured photo sensitive material, and can be provided in a film form or in a liquid form. For example, the second dielectric layer 5 can be formed from a “negative” acting material, such as epoxy resins or acrylic resins. Such a “negative” acting material is a type of resin in which the portion of the resin exposed to a radiation source (e.g. UV source) becomes insoluble to the developer. The unexposed portion of the resin is dissolved in the developer (e.g. an organic solvent). The second dielectric layer 5 includes a first portion 51 and a second portion 52. The first portion 51 is disposed on the sidewall 341 of the through hole 34 of the base material 3 and on the gradient surface 44 of the first dielectric layer 4 The second portion 52 is disposed on the second surface 32 of the base material 3. For example, the first portion 51 of the second dielectric layer 5 covers the gradient surface 44 of the intermediate portion 43 of the first dielectric layer 4, but does not cover the inner surface 46 of the intermediate portion 43 of the first dielectric layer 4. In some embodiments, a surface 511 of the first portion 51 of the second dielectric layer 5 is substantially coplanar with the inner surface 46 of the first dielectric layer 4.

The first portion 51 of the second dielectric layer 5 has a thickness T₁, and the second portion 52 of the second dielectric layer 5 has a thickness T₂. The thickness T₁ of the first portion 51 of the second dielectric layer 5 is greater than the thickness T₂ of the second portion 52 of the second dielectric layer 5. In some embodiments, the thickness T₂ of the second portion 52 of the second dielectric layer 5 may be, e.g., about 5% to about 60%, about 10% to about 50%, or about 15% to about 50% of the thickness T₁ of the first portion 51 of the second dielectric layer 5. For example, the thickness T₁ of the first portion 51 of the second dielectric layer 5 may be, e.g., about 1 μm to about 30 μm, about 2 μm to about 20 μm, about 5 μm to about 15 μm, or about 7 μm to about 15 μm. The thickness T₂ of the second portion 52 of the second dielectric layer 5 may be, e.g., about 0.1 μm to about 20 μm, about 0.2 μm to about 15 μm, about 0.5 μm to about 12 μ, or about 1 μm to about 11 μm. In some embodiments, the second portion 52 of the second dielectric layer 5 may have a surface roughness (Ra) of, e.g., about 0.001 μm to about 0.1 μm, about 0.002 μm to about 0.05 μm, about 0.005 μm to about 0.03 μm, or about 0.008 μm to about 0.026 μm.

The first conductive layer 6 is disposed on the first dielectric layer 4. The material of the first conductive layer 6 includes, for example, conductive metal such as aluminum, copper, or another metal or metal alloy, other electrically conductive material, or a combination of two or more thereof. The first conductive layer 6 includes a first surface 61 and a second surface 62 opposite to the first surface 61. The second surface of the 62 of the first conductive layer 6 faces and is disposed on the first surface 41 of the first dielectric layer 4. A portion of the second surface 62 of a first portion 63 of the first conductive layer 6 is uncovered by the first dielectric layer 4. For example, the opening 48 of the first dielectric layer 4 in the through hole 34 of the base material 3 exposes the portion of the second surface 62 of the first portion 63 of the first conductive layer 6. The intermediate portion 43 of the first dielectric layer 4 is interposed between the first portion 51 of the second dielectric layer 5 and the first conductive layer 6.

The second conductive layer 7 is disposed on the second dielectric layer 5 and physically contacts the first conductive layer 6. The material of the second conductive layer 7 includes, for example, conductive metal such as copper or another metal or metal alloy, other electrically conductive material, or a combination of two or more thereof. In some embodiments, the second conductive layer 7 is disposed on the second portion 52 of the second dielectric layer 5 and extends into the through hole 34, so as to cover the surface 511 of the first portion 51 of the second dielectric layer 5, the inner surface 46 of the first dielectric layer 4, and the second surface 62 of the first portion 63 of the first conductive layer 6.

In some embodiments, the first conductive layer 5 may include one or more bonding pads. FIG. 2A illustrates a cross-sectional view of a portion of a package structure including a via structure according to some embodiments of the present disclosure. The via structure 2 of FIG. 2A is similar to the via structure 2 as shown in FIG. 2, except that the first conductive layer 6 includes at least one bonding pad 69. The second conductive layer 7 is connected to the bonding pad 69. In the via structure 2 shown in FIG. 2A, the first portion 63 of the first conductive layer 6 includes the bonding pad 69.

Referring back to FIG. 1 and FIG. 2, the active layer 11 is disposed on the first surface 61 of the first conductive layer 6 for external connection purpose. In one embodiment, the active layer 11 may include a plurality of circuit layers (not shown) and a plurality of electrical elements (not shown). The passivation layer 12 is disposed on the second conductive layer 7 and the second dielectric layer 5, and may fill a space defined by the second conductive layer 7 in the through hole 34. The material of the passivation layer 12 may include, for example, a non-conductive film (NCF), a non-conductive paste (NCP), or a combination thereof. The passivation layer 12 defines a plurality of openings 121 to expose portions of the second conductive layer 7. The UBM layers 13 are disposed in respective one of the openings 121, and physically connected to the exposed second conductive layer 7. The solder balls 14 are disposed on respective one of the UBM layers 13 in the openings 121 for external connection, and are electrically connected to the second conductive layer 7 through the UBM layers 13.

According to at least some embodiments of the present disclosure, as shown in the embodiment illustrated in FIG. 1 and FIG. 2, the size of the chamfer portion 36 may be small, and significantly reduce light beams reflected by the chamfer portion 36. In addition, since a part of the first conductive layer 6 adjacent to the sidewall 341 of the through hole 34 is covered by the intermediate portion 43 of the first dielectric layer 4, no light beams or a small amount of light beams are reflected by the intermediate portion 43 of the first dielectric layer 4. Thus, light beams reflected by the part of the first conductive layer 6 at the bottom of the through hole may be reduced or avoided. Accordingly, nodules of the second dielectric layer 5 may be reduced or avoided, and the yield rate of the via structure 2 may be improved by, e.g., more than about 30%, more than about 40%, more than about 50%, more than about 60%, or more than about 70%. Further, since the second portion 52 of the second dielectric layer 5 has a reduced thickness, warpage (e.g., bending or twisting) of the substrate structure 1 is also reduced.

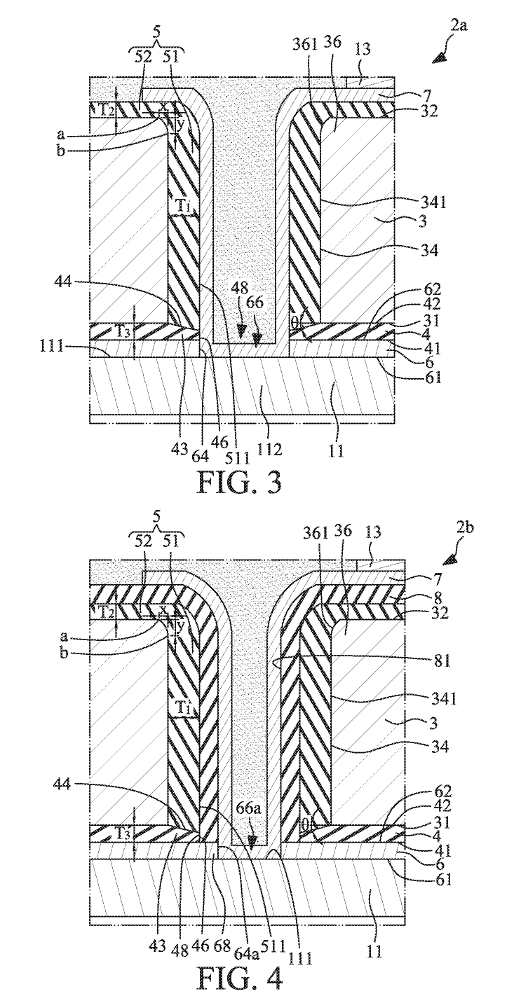

In some embodiments, some components of the via structure 2 as shown in FIG. 1 and FIG. 2 may be omitted or removed. FIG. 3 illustrates an example of a via structure 2a according to some embodiments of the present disclosure. The via structure 2a of FIG. 3 is similar to the via structure 2 as shown in FIG. 2, except that the first portion 63 of the first conductive layer 6 of FIG. 2 may be omitted or removed, so that the first conductive layer 6 includes an inner surface 64 defining an opening 66 to expose a surface 111 of a first portion 112 of the active layer 11. In some embodiments, the inner surface 64 of the first conductive layer 6 is substantially coplanar with the inner surface 46 of the first dielectric layer 4 and the surface 511 of the first potion 51 of the second dielectric layer 5. The size of the opening 66 may be substantially the same as the size of the opening 48. Accordingly, the second conductive layer 7 further covers the inner surface 64 of the first conductive layer 6 and the portion of the surface 111 of the first portion 112 of the active layer 11. In this way, the second conductive layer 7 can be electrically connected to and physically contact the first conductive layer 6 and the active layer 11 directly.

In some embodiments, a via structure may include other components in addition to components of the via structure 2 as shown in FIG. 1 and FIG. 2. FIG. 4 illustrates an example of a via structure 2b according to some embodiments of the present disclosure. The via structure 2a of FIG. 4 is similar to the via structure 2 as shown in FIG. 2, except that the via structure 2b further includes a third dielectric layer 8 and a first part 68 of the first conductive layer 6. The third dielectric layer 8 is disposed on the second dielectric layer 5, and the second conductive layer 7 is disposed on the third dielectric layer 8. That is, the third dielectric layer 8 is interposed between the second dielectric layer 5 and the second conductive layer 7. The material of the third dielectric layer 8 may be the same as or different from the material of the second dielectric layer 5. The first part 68 of the first conductive layer 6 is exposed from the opening 48 of the first dielectric layer 4. The third dielectric layer 8 covers the first portion 51 and the second portion 52 of the second dielectric layer 5, the inner surface 46 of the first dielectric layer 4 and the first part 68 of the first conductive layer 6. In some embodiments, the first part 68 of the first conductive layer 6 includes an inner surface 64a defining an opening 66a to expose a portion of the surface 111 of the active layer 11. The inner surface 64a of the first conductive layer 6 may be substantially coplanar with a surface 81 of the third dielectric layer 8 in the through hole 34. Accordingly, the second conductive layer 7 covers the surface 81 of the third dielectric layer 8, the inner surface 64a of the first conductive layer 6, and the exposed portion of the surface 111 of the active layer 11. The second conductive layer 7 can be electrically connected to and physically contact the first conductive layer 6 and the active layer 11 directly.

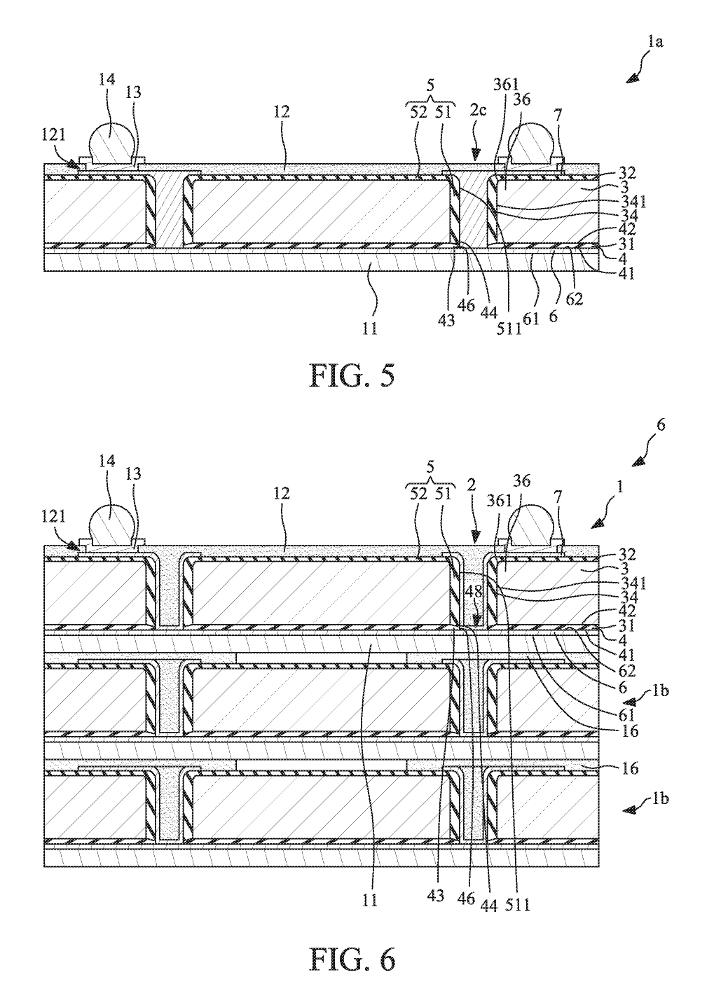

FIG. 5 illustrates an example of a substrate structure 1a including a via structure 2c according to some embodiments of the present disclosure. The via structure 2c of FIG. 5 is similar to the via structure 2 as shown in FIG. 2, except that the second conductive layer 7 fills a space defined by the surface 511 of the first portion 51 of the second dielectric layer 5, the inner surface 46 of the intermediate portion 43 of the first dielectric layer 4 and the second surface 62 of the first conductive layer 6.

In some embodiments, multiple substrate structures may be stacked together. FIG. 6 illustrates a stacked structure 6 including a plurality of substrate structure according to some embodiments of the present disclosure. The stacked structure 6 of FIG. 6 includes a substrate structure 1 and a plurality of substrate structures 1b. The substrate structure 1 of FIG. 6 may be the same as the substrate structure 1 as shown in FIG. 1. The substrate structure 1b is similar to the substrate structure 1 as shown in FIG. 1, except that the solder ball 14 may be omitted. The two substrate structures 1b are stacked together, and at least one solder layer 16 may be disposed therebetween to connect the active layer 11 of the upper one of the two substrate structures 1b and the second conductive layer 7 of the lower one of the two substrate structures 1b. The substrate structure 1 is disposed above the two substrate structures 1b , and at least another solder layer 16 is disposed therebetween to connect the active layer 11 of the substrate structure 1 and the second conductive layer 7 of the upper one of the two substrate structures 1b.

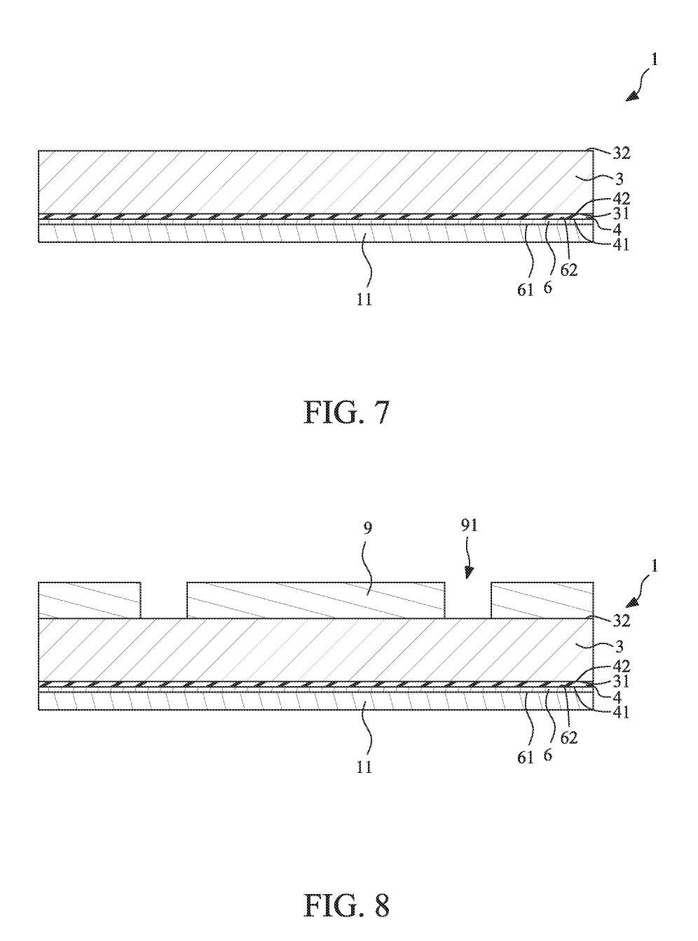

FIG. 7 to FIG. 19 illustrate various stages of an example of a method for manufacturing a via structure according to some embodiments of the present disclosure. In the illustrated embodiments, the method is used to manufacture a via structure such as the via structure 2 shown in FIG. 1 and FIG. 2. Referring to FIG. 7, a substrate 1 is provided. The substrate 1 includes a base material 3, a first dielectric layer 4 and an active layer 11. The base material 3 includes a first surface 31 and a second surface 32 opposite to the first surface 31. For example, the material of the base material 3 may include, for example, a semiconductor material (e.g., silicon), glass, ceramic, organic material, metal (e.g. Cu, Ni, Ag/Sn, and Pd), or a combination of two or more thereof. The first dielectric layer 4 is disposed on the first surface 31 of the base material 3. The material of the first dielectric layer 4 may include, for example, oxides, nitrides, or a combination of two or more thereof. The first dielectric layer 4 may include a first surface 41 and a second surface 42 opposite to the first surface 41. The second surface 42 of the first dielectric layer 4 faces and is disposed on the first surface 31 of the base material 3. The first conductive layer 6 is disposed on the first dielectric layer 4. The material of the first conductive layer 6 may include, for example, conductive metal such as copper, aluminum or another metal or metal alloy, other electrically conductive material, or a combination of two or more thereof. The first conductive layer 6 includes a first surface 61 and a second surface 62 opposite to the first surface 61. The second surface of the 62 of the first conductive layer 6 faces and is disposed on the first surface 41 of the first dielectric layer 4. The optional active layer 11 is disposed on the first surface 61 of the first conductive layer 6.

Referring to FIG. 8, a photoresist layer 9 is formed as a mask on the base material 3 and covers the second surface 32 of the base material 3. The photoresist layer 9 defines at least one opening 91 which expose a portion of the second surface 32 of the base material 3.

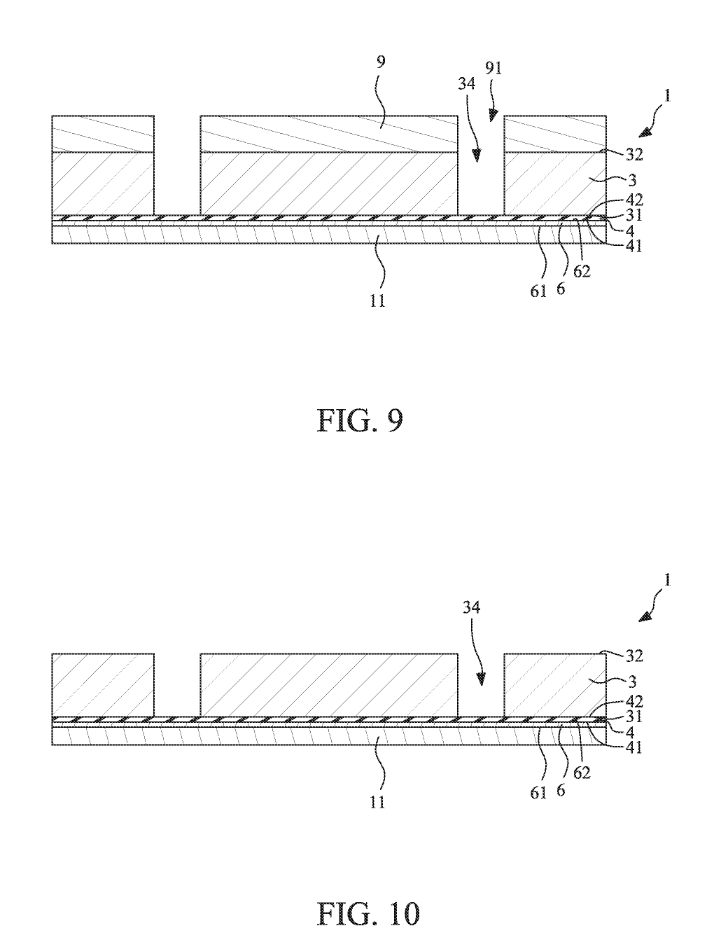

Referring to FIG. 9, a dry etching process is conducted to the base material 3, with the photoresist layer 9 serving as a mask. A through hole 34 is formed on the base material 3 at a position corresponding to the opening 91 of the photoresist layer 9, and extends through the base material 3. A portion of the second surface 42 of the first dielectric layer 4 is exposed in the through hole 34.

Referring to FIG. 10, the photoresist layer 9 is then removed by, for example, stripping.

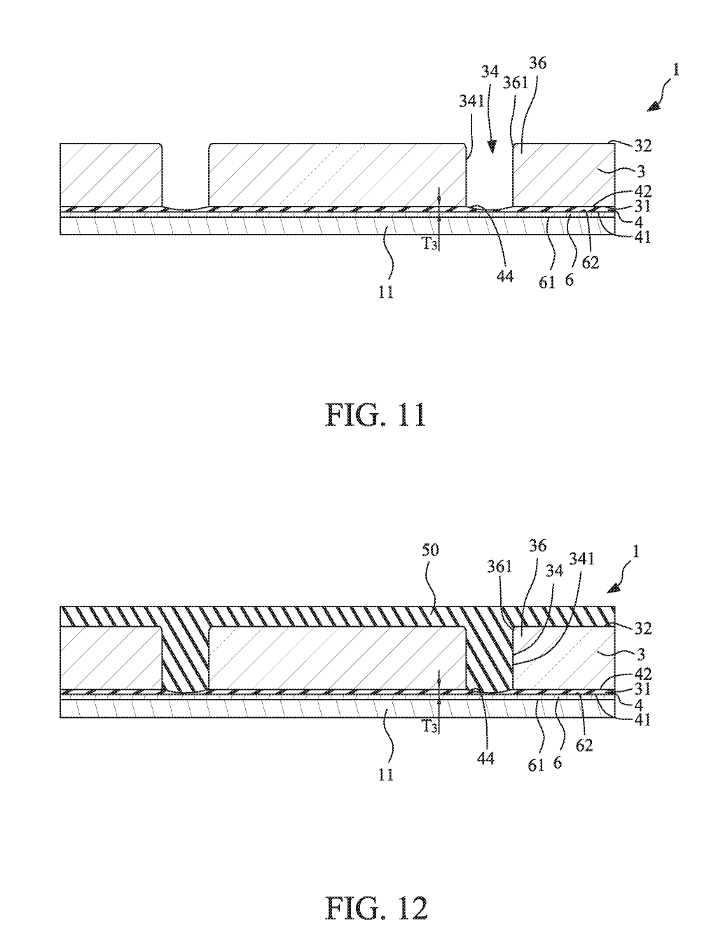

Referring to FIG. 11, a first partial etching process is conducted to the first dielectric layer 4, so as to remove at least a part of an exposed portion of the first dielectric layer 4 in the through hole 34. A thickness T₃ of the first dielectric layer 4 thus decreases along a direction from a sidewall 341 of the through hole 34 to a center of the through hole 34, forming a gradient surface 44 extending downward from the sidewall 341 toward the center of the through hole 34. After the first partial etching process, a remaining part of the exposed portion of the first dielectric layer 4 covers the first conductive layer 6. For example, the first partial etching process reduces the thickness T₃ of the first dielectric layer 4 in the through hole 34, without etching away the first dielectric layer 4 completely. The first partial etching process may further include removing a part of the base material 3, thus forming a chamfer portion 36 at an edge of the base material 3 adjacent to the top portion of the through hole 34.

Since the first partial etching process removes a part of the exposed portion of the first dielectric layer 4 in the through hole 34 without etching away the first dielectric layer 4 completely, a process time t₁ thereof may be significantly less than that of a process for completely etching the exposed portion of the first dielectric layer 4 in the through hole 34. Hence, the portion of the base material 3 removed in the first partial etching process is small, and a size of the chamfer portion 36 can be reduced. For example, a surface 361 of the chamfer portion 36 intersects with the second surface 32 of the base material 3 at a point “a”, and intersects with the sidewall 341 of the through hole 34 at a point “b” (as shown in FIG. 2). A distance “x” (as shown in FIG. 2) between the point “a” and the sidewall 341 of the through hole 34 is measured along the second surface 32 of the base material 3. In some embodiments, the distance “x” may be, e.g., from about 0.01 μm to about 10 μm, from about 0.01 μm to about 5 μm, from about 0.01 μm to about 2.25 μm, from about 0.01 μm to about 1 μm, or from about 0.01 μm to about 0.5 μm. In one embodiment, for example, 0.01 μm≤x≤2.25 μm. A distance “y” (as shown in FIG. 2) between the point “b” and the second surface 32 of the base material 3 is measured along the sidewall 341 of the through hole 34. The distance “y” may be greater than or equal to the distance “x.”

Referring to FIG. 12, a photoimageable dielectric material (or a photo sensitive material) 50 is disposed on the base material 3 and in the through hole 34. The photoimageable dielectric material 50 covers the second surface 32 of the base material 3 and the sidewall 341 of the through hole, and fills the through hole 34. The photoimageable dielectric material 50 may be provided in a film form or solidified from a liquid form. For example, the photoimageable dielectric material 50 may be a negative acting material.

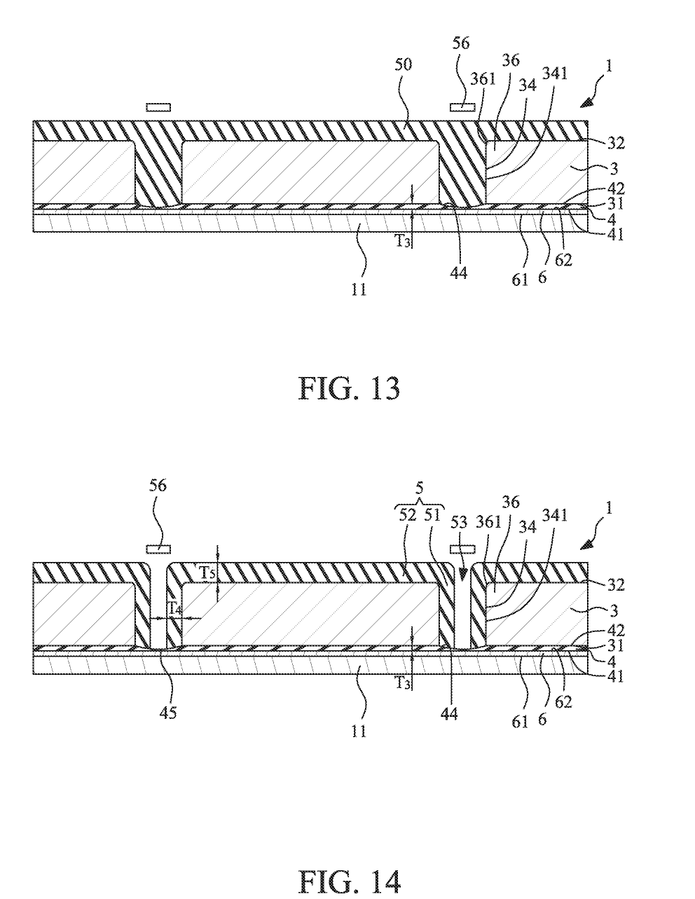

Referring to FIG. 13, a mask 56 is provided above the photoimageable dielectric material 50, and then the photoimageable dielectric material 50 is exposed to a radiation source (e.g. ultraviolet (UV) source).

Referring to FIG. 14, after radiation, the photoimageable dielectric material 50 is developed by a developer (e.g. an organic solvent) to form a second dielectric layer 5. A portion of the photoimageable dielectric material 50 exposed to the radiation source becomes insoluble to the developer, and the unexposed portion (corresponding to the location of the mask) of the photoimageable dielectric material 50 is dissolved in a developer. Thus, a second dielectric layer 5 is formed as shown in FIG. 14. The second dielectric layer 5 includes a first portion 51 disposed on the gradient surface 44 of the first dielectric layer 4 and on the sidewall 341 of the through hole 34, and a second portion 52 disposed on the second surface of the base material 3. The first portion 51 of the second dielectric layer 5 has a thickness T₄, and the second portion 52 of the second dielectric layer 5 has a thickness T₅. In one embodiment, T₅ may be greater than T₄. The first portion 51 of the second dielectric layer 5 covers a portion of the gradient surface 44 of the first dielectric layer 4, and defines a central hole 53. Hence, the first dielectric layer 4 includes a first portion 45 exposed in the central hole 53 and uncovered by the second dielectric layer 5.

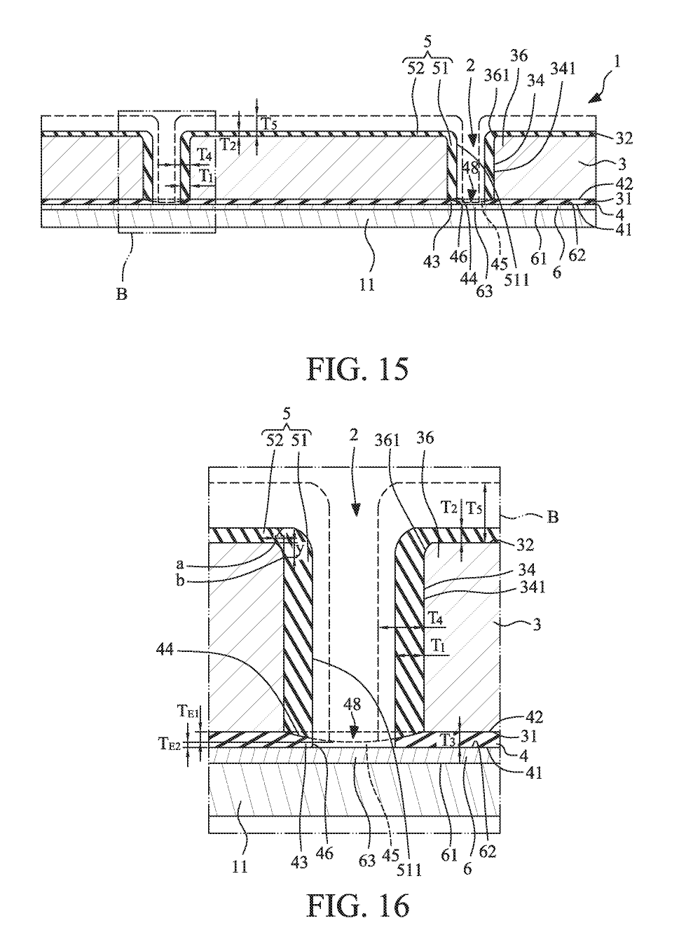

Referring to FIG. 15, a second partial etching process is conducted to remove the first portion 45 of the first dielectric layer 4 so as to form the intermediate portion 43 of the first dielectric layer 4. For example, the second dielectric layer 5 serves as a mask for etching the first dielectric layer 4. After the second partial etching process, the inner surface 46 of the intermediate portion 43 defines an opening 48, and a portion of the second surface 62 of the first portion 63 of the first conductive layer 6 is uncovered by the first dielectric layer 4 and is exposed in the opening 48. A surface 511 of the first portion 51 of the second dielectric layer 5 and the inner surface 46 of the first dielectric layer 4 are formed and are substantially coplanar with each other. Thus, the via structure 2 is formed.

The second partial etching process further includes removing a part of the first portion 51 of the second dielectric layer 5 and a part of the second portion 52 of the second dielectric layer 5. After the process, the remaining part of the first portion 51 of the second dielectric layer 5 has a thickness T₁, and the remaining part of the second portion 52 of the second dielectric layer 5 has a thickness T₂. A thickness of the part removed from the first portion 51 of the second dielectric layer 5 may be defined as T₄-T₁, and a thickness of the part removed from the second portion 52 of the second dielectric layer 5 may be defined as T₅-T₂. The thickness (T₄-T₁) of the part removed from the first portion 51 of the second dielectric layer 5 may be less than the thickness (T₅-T₂) of the part removed from the second portion 52 of the dielectric layer 5. In some embodiments, the thickness T₂ of the second portion 52 of the second dielectric layer 5 may be, e.g., about 5% to about 60%, about 10% to about 50%, or about 15% to about 50% of the thickness T₁ of the first portion 51 of the second dielectric layer 5. For example, the thickness T₁ of the first portion 51 of the second dielectric layer 5 may be, e.g., about 1 μm to about 30 μm, about 2 μm to about 20 μm, about 5 μm to about 15 μm, or about 7 μm to about 15 μm, and the thickness T₂ of the second portion 52 of the second dielectric layer 5 may be, e.g., about 0.1 μm to about 20 μm, about 0.2 μm to about 15 μm, about 0.5 μm to about 12 μm, or about 1 μm to about 11 μm. In some embodiments, the second portion 52 of the second dielectric layer 5 may have a surface roughness (Ra) of, e.g., about 0.001 μm to about 0.1 μm, about 0.002 μm to about 0.05 μm, about 0.005 μm to about 0.03 μm, or about 0.008 μm to about 0.026 μm.

FIG. 16 illustrates an enlarged view of the area B in FIG. 15. In the method described above, a thickness of the first dielectric layer 4 before the first partial etching process is defined as T₃. A thickness of a part of the first dielectric layer 4 which is removed during the first partial etching process is defined as T_{E1}, and a thickness of another part of the first dielectric layer 4 which is removed during the second partial etching process is defined as T_{E2}. An etching rate of the first dielectric layer 4 during the first partial etching process is defined as E_{O1}, and an etching rate of the first dielectric layer 4 during the second partial etching process is defined as E_{O2}. A process time of the first partial etching process is defined as t₁, and a process time of the second partial etching process is defined as t₂. Accordingly, the thickness T₅ of the first dielectric layer 4 before the first partial etching process can be expressed as Equation (1) below.

T₃=T_{E1}+T_{E2}=E_{O1}×t₁+E_{O2}×t₂ (1)

A thickness of the second portion 52 of the second dielectric layer 5 before the second partial etching process is defined as T₅, and a thickness of a remaining part of the second portion 52 of the second dielectric layer 5 after the second partial etching process is defined as T₂. An etching rate of the second dielectric layer 5 during the second partial etching process is defined as E_{PA}. Hence, the thickness T₂ can be expressed as Equation (2) below.

T₂=T₅−E_{PA}×t₂ (2)

Due to the exposure concerns, the thickness T₂ of the remain part of the second portion 52 of the second dielectric layer 5 after the second partial etching process may be equal to or greater than a predetermined value, thus the above Equation (2) is modified into Equation (3) below.

t₂≤(T₂−T₅)/E_{PA} (3)

In addition, the thickness T_{E1} of the part of the first dielectric layer 4 which is removed during the first partial etching process may be equal to or less than the thickness T₃ of the first dielectric layer 4 before the first partial etching process, which is expressed as Equation (4) below.

t₁×E_{O1}≤T₃ or t₁≤T₃/E_{O1} (4)

Combining Equation (1) to Equation (4) above, a process window of the process time t₁ of the first partial etching process can be expressed as Equation (5) below.

T₃/E_{O1}≥t₁≥{T₃−E_{O2}×[(T₅−T₂)/E_{PA}]}/E_{O1} (5)

According to a general etching theory, the distance “x” between the point “a” and the sidewall 341 of the through hole 34 can be expressed as a function of the process time t₁, as shown in Equation (6) below. In the Equation (6), “C” and “D” each represents a constant.

x=D×t₁+C (6)

Combining Equation (5) and the Equation (6) above, an appropriate range of the distance “x” is shown as Equation (7) below.

C+D×T₃/E_{O1}≥x≥C+D×{T₃−E_{O2}×[(T₅−T₂)/E_{PA}]}/E_{O1} (7)

The constants “C” and “D” can be obtained through experiments. The thickness of the first dielectric layer T₅ is predetermined, and the rates E_{O1}, E_{O2} and E_{PA} can be obtained. Hence, the value “x” can be used as an index for assessing the etching status (e.g. the thickness of the remaining part) of the first conductive layer 6. For example, in some embodiments, the constant “C” may be, e.g., about 0.1, about 0.2, or about 0.5, and the constant “D” may be about 0.001, about 0.005, about 0.008, or about 0.01. In some embodiments, the range of the distance “x” may be , e.g., from about 0.01 μm to about 10 μm, from about 0.01 μm to about 5 μm, from about 0.01 μm to about 2.25 μm, from about 0.01 μm to about 1 μm, or from about 0.01 μm to about 0.5 μm. In one embodiment, for example, 0.01 ∥m≤x≤2.25 μm.

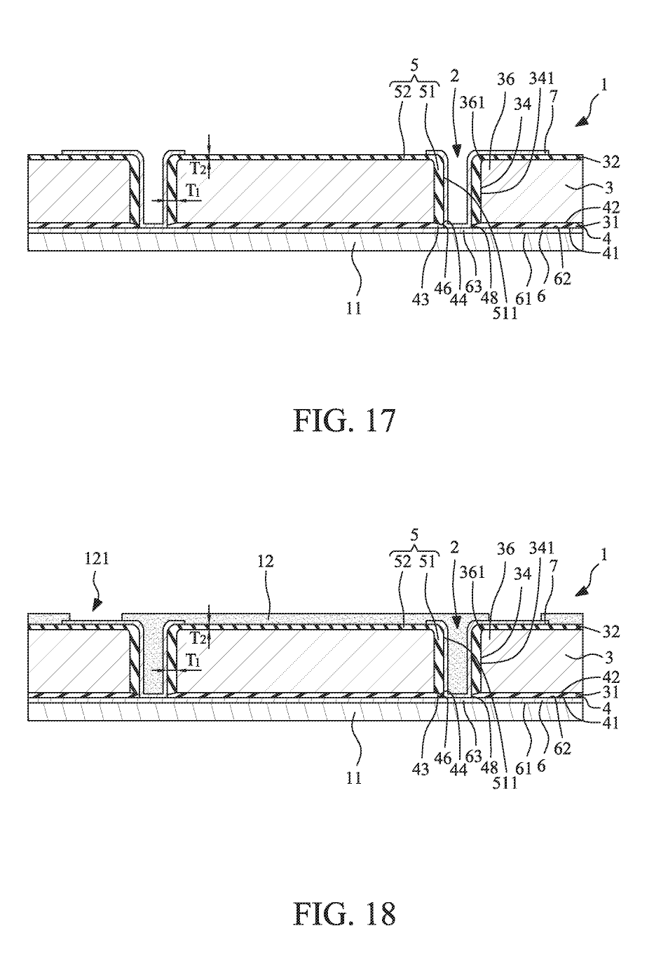

Referring to FIG. 17, in some embodiments, a second conductive layer 7 may be formed on the second dielectric layer 5 and physically contacts the first portion 63 of the first conductive layer 6. The material of the second conductive layer 7 includes, for example, conductive metal such as copper or another metal or metal alloy, other electrically conductive material, or a combination of two or more thereof In some embodiments, the second conductive layer 7 is disposed on the second portion 52 of the second dielectric layer 5 and extends into the through hole 34, so as to cover the surface 511 of the first portion 51 of the second dielectric layer 5, the inner surface 46 of the first dielectric layer 4, and the portion of the second surface 62 of the first portion 63 of the first conductive layer 6.

Referring to FIG. 18, the passivation layer 12 is then formed on the second conductive layer 7 and the second dielectric layer 5, and fills a space defined by the second conductive layer 7 in the through hole 34. The material of the passivation layer 12 may include, for example, a NCF, a NCP or a combination thereof. The passivation layer 12 defines one or more openings 121 to expose portions of the second conductive layer 7.

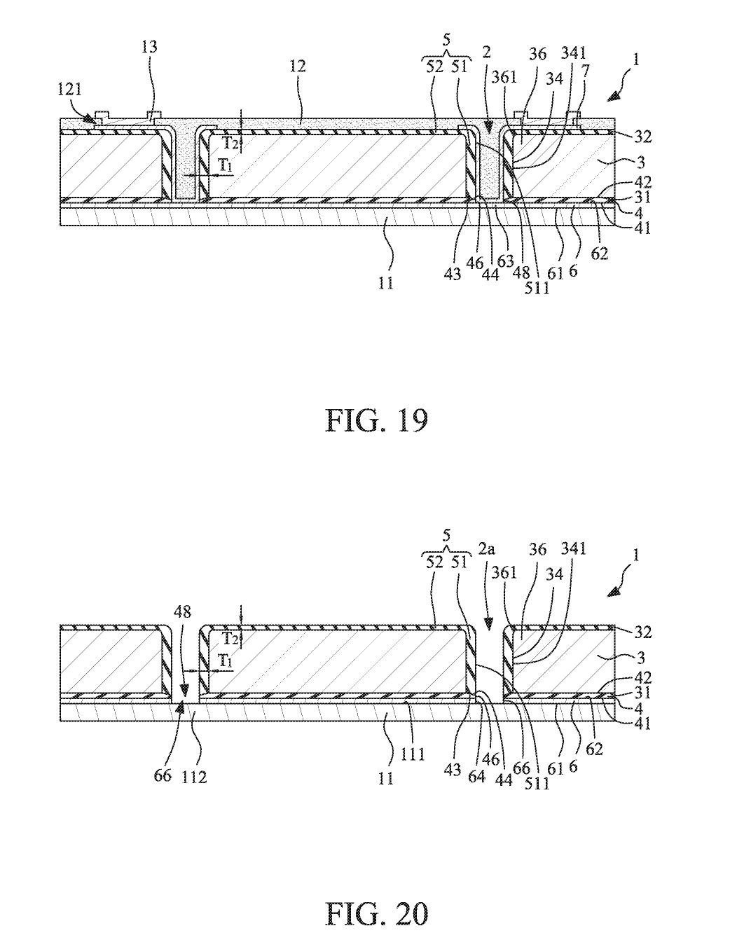

Referring to FIG. 19, an UBM layer 13 is formed in each opening 121 to contact the exposed second conductive layer 7. Then, a solder ball 14 is formed on the UBM layer 13, thus forming the substrate structure 1 and the via structure 2 as shown in FIG. 1 and FIG. 2.

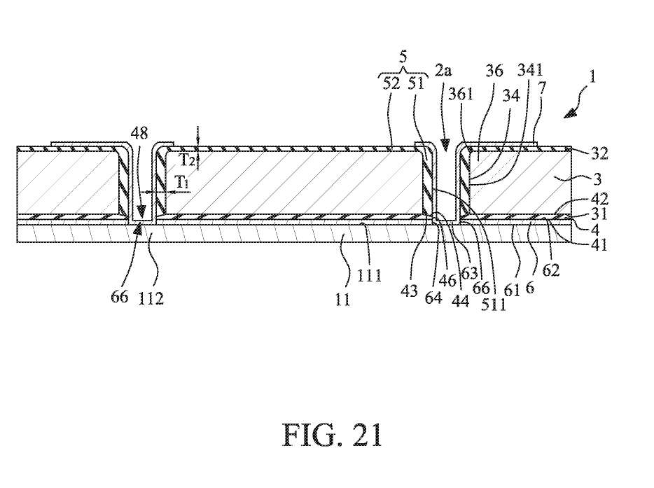

FIGS. 20 and 21 illustrate various stages of an example of a method for manufacturing a via structure according to some embodiments of the present disclosure. In the illustrated embodiments, the method is used to manufacture a via structure such as the via structure 2a shown in FIG. 3. The initial stages of the illustrated process may be the same as the stages illustrated in FIG. 9 to FIG. 14. FIG. 20 depicts a stage subsequent to that depicted in FIG. 14. Referring to FIG. 20, a second partial etching process is conducted to remove the first portion 45 of the first dielectric layer 4 and the first portion 63 of the first conductive layer 6. For example, the second dielectric layer 5 serves as a mask for etching the first dielectric layer 4 and the first conductive layer 6. After the second partial etching process, the intermediate portion 43 of the first dielectric layer 4 is formed. The inner surface 46 of the intermediate portion 43 defines an opening 48. Besides, the first conductive layer 6 thus includes an inner surface 64 defining an opening 66 to expose a surface 111 of a first portion 112 of the active layer 11. The size of the opening 66 may be substantially the same as the size of the opening 48. A surface 511 of the first portion 51 of the second dielectric layer 5, the inner surface 46 of the first dielectric layer 4 and the inner surface 64 of the first conductive layer 6 are formed and are substantially coplanar with each other. Thus, the via structure 2a is formed.

The second partial etching process may also include removing a part of the first portion 51 of the second dielectric layer 5 and a part of the second portion 52 of the second dielectric layer 5. After the process, the remaining part of the first portion 51 of the second dielectric layer 5 has a thickness T₁, and the remaining part of the second portion 52 of the second dielectric layer 5 has a thickness T₂. A thickness of the part removed from the first portion 51 of the second dielectric layer 5 is defined as T₄-T₁, and a thickness of the part removed from the second portion 52 of the second dielectric layer 5 is defined as T₅-T₂. The thickness (T₄-T₁) of the part removed from the first portion 51 of the second dielectric layer 5 is less than the thickness (T₅-T₂) of the part removed from the second portion 52 of the dielectric layer 5. In some embodiments, the thickness T₂ of the second portion 52 of the second dielectric layer 5 may be, e.g., about 5% to about 60%, about 10% to about 50%, or about 15% to about 50% of the thickness T₁ of the first portion 51 of the second dielectric layer 5. For example, the thickness T₁ of the first portion 51 of the second dielectric layer 5 may be, e.g., about 1 μm to about 30 μm, about 2 μm to about 20 μm, about 5 μm to about 15 μm, or about 7μm to about 15 μm, and the thickness T₂ of the second portion 52 of the second dielectric layer 5 may be, e.g., about 0.1 μm to about 20 μm, about 0.2 μm to about 15 μm, about 0.5 μm to about 12 μm, or about 1 μm to about 11 μm. In some embodiments, the second portion 52 of the second dielectric layer 5 has a surface roughness (Ra) of, e.g., about 0.001 μm to about 0.1 μm, about 0.002 μm to about 0.05 μm, about 0.005 μm to about 0.03 μm, or about 0.008 μm to about 0.026 μm.

Referring to FIG. 21, in some embodiments, a second conductive layer 7 may be formed on the second dielectric layer 5 and physically contacts the first portion 112 of the active layer 11. The material of the second conductive layer 7 includes, for example, conductive metal such as copper or another metal or metal alloy, other electrically conductive material, or a combination of two or more thereof. In some embodiments, the second conductive layer 7 is disposed on the second portion 52 of the second dielectric layer 5 and extends into the through hole 34, so as to cover the surface 511 of the first portion 51 of the second dielectric layer 5, the inner surface 46 of the first dielectric layer 4, the inner surface 64 of the first conductive layer 6, and the surface 111 of the first portion 112 of the active layer 11.

Then, similar to the stage illustrated in FIG. 18, the passivation layer 12 is formed on the second conductive layer 7 and the second dielectric layer 5, and fills a space defined by the second conductive layer 7 in the through hole 34. The material of the passivation layer 12 may include, for example, a NCF, a NCP, or a combination thereof. The passivation layer 12 defines one or more openings 121 to expose portions of the second conductive layer 7.

Then, similar to the stage illustrated in FIG. 19, an UBM layer 13 is formed in each opening 121 to contact the exposed second conductive layer 7. Then, at least one solder ball 14 is formed on the UBM layer 13, thus forming the via structure 2a as shown in FIG. 3.

In some embodiments, referring to FIG. 15 again, the first dielectric layer 4 has an inner surface 46 defining an opening 48, and the first portion 63 of the first conductive layer 6 exposed from the opening 48 may be removed during the process. In some embodiments, however, if a process time t₂ of the second partial etching process is longer than a predetermined value, a part of the first conductive layer 6 may also be removed. For example, the first portion 63 of the first conductive layer 6 exposed from the opening 48 may be removed, forming the via structure as shown in FIG. 20. The first conductive layer 6 includes an inner surface 64 exposed in the through hole 34. Then, a second conductive layer 7 and a passivation layer 8 are formed, thus forming the via structure 2a as shown in FIG. 3. The second conductive layer 7 contacts the inner surface 64 of the first conductive layer 6 and is electrically connected to the first conductive layer 6. As a result, the first portion of the second dielectric layer does not cover the inner surface of the first dielectric layer and the inner surface of the first conductive layer. Thus, the second conductive layer may be electrically connected to and may physically contact the inner surface of the first conductive layer.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A via structure, comprising:
a base material including a first surface and a second surface opposite to the first surface, and defining at least one through hole;
a first dielectric layer disposed on the first surface of the base material and including a gradient surface extending from a sidewall of the through hole of the base material downward toward a center of the through hole; and
a second dielectric layer disposed on the gradient surface of first dielectric layer.

2. The via structure of claim 1, wherein the base material includes a semiconductor material.

3. The via structure of claim 1, wherein the second dielectric layer includes a first portion disposed on the sidewall of the through hole of the base material and on the gradient surface of the first dielectric layer, and a second portion disposed on the second surface of the base material.

4. The via structure of claim 3, wherein a thickness of the first portion of the second dielectric layer is greater than a thickness of the second portion of the second dielectric layer.

5. The via structure of claim 4, wherein the thickness of the second portion is about 15% to about 50% of the thickness of the first portion.

6. The via structure of claim 1, wherein a thickness of the first dielectric layer decreases from the sidewall of the through hole of the base material to the center of the through hole.

7. The via structure of claim 1, wherein a material of the second dielectric layer includes a cured photo sensitive material.

8. The via structure of claim 1, further comprising a conductive layer disposed on the first dielectric layer, wherein a portion of a surface of the conductive layer is uncovered by the first dielectric layer.

9. The via structure of claim 1, wherein the base material includes a chamfer portion at an edge adjacent to the through hole.

10. The via structure of claim 9, wherein a surface of the chamfer portion intersects with the second surface of the base material at a point, a distance between the point and the sidewall of the through hole measured along the second surface of the base material is from about 0.01 μm to about 2.25 μm.

11. A substrate structure comprising:
a base material including a first surface and a second surface opposite to the first surface, and defining least one through hole; and
a first dielectric layer disposed on the first surface of the base material and including a gradient surface extending from a sidewall of the through hole downward toward a center of the through hole.

12. The substrate structure of claim 11, wherein a thickness of the first dielectric layer decreases from the sidewall of the through hole to the center of the through hole.

13. The substrate structure of claim 11, further comprising a second dielectric layer including a first portion disposed on the sidewall of the through hole and a second portion disposed on the second surface of the base material.

14. The substrate structure of claim 13, wherein a thickness of the first portion is greater than a thickness of the second portion.

15. The substrate structure of claim 13, further comprising a first conductive layer disposed on the first dielectric layer, and at least a portion of a surface of the first conductive layer is exposed in the through hole.

16. The substrate structure of claim 15, wherein the first dielectric layer includes an intermediate portion interposed between the first portion of the second dielectric layer and the first conductive layer, the intermediate portion includes the gradient surface and defines at least one opening to expose the portion of the surface of the first conductive layer.

17. The substrate structure of claim 15, further comprising a second conductive layer disposed on the second dielectric layer and physically contacting the first conductive layer.

18. The substrate structure of claim 17, wherein the first conductive layer includes at least one bonding pad, and the second conductive layer is connected to the bonding pad.

19.-25. (canceled)

26. The via structure of claim 1, wherein the first dielectric layer includes a first surface and a second surface opposite to the first surface of the first dielectric layer, the second surface of the first dielectric layer faces and is disposed on the first surface of the base material, and an angle between the gradient surface of the first dielectric layer and the second surface of the first dielectric layer is from about 0.05 degree to about 15 degrees.

27. The via structure of claim 1, wherein the first dielectric layer includes a first surface and a second surface opposite to the first surface of the first dielectric layer, the second surface of the first dielectric layer faces and is disposed on the first surface of the base material, and the gradient surface connects to the second surface of the first dielectric layer and is exposed in the through hole of the base material.
